(19) United States
(12) Patent Application Publication
(10) Pub. No.: US 2010/0014036 A1
(43) Pub. Date: Jan. 21, 2010

(54) ALIGNMENT LAYER OF LIQUID CRYSTALS DEPOSITED AND RUBBED BEFORE MAKING MICROSTRUCTURES

(75) Inventor: Stephane CAPLET, Sassenage (FR)

Correspondence Address: Nixon Peabody LLP, P.O. Box 60610, Palo Alto, CA, 94306, US

(73) Assignee: COMMISSARIAT A L'ENERGIE ATOMIQUE, Paris (FR)

(21) Appl. No.: 12/502,061

(22) Filed: Jul. 13, 2009

(30) Foreign Application Priority Data
Jul. 15, 2008 (FR) FR 08 54796

(51) Int. Cl. G02F 1/1337; H01L 21/64

(52) U.S. Cl. 349/124; 438/30; 257/E21.001

(57) ABSTRACT

A process for formation of cavities of a micro-optic device, comprising: a) formation, on the surface plane of a support, of an alignment layer of liquid crystals; and b) formation of walls of said cavities, the base of said cavities being formed by said alignment layer.

### CROSS REFERENCE TO RELATED APPLICATIONS OR PRIORITY CLAIM

This application claims priority of French Patent Application No. 08 54796, filed Jul. 15, 2008.

### TECHNICAL FIELD AND PRIOR ART

The invention relates to making devices containing hermetic cavities of micronic dimensions delimited by walls, into which a functional fluid—in this case liquid crystals—is introduced.

The invention applies to fields in which liquid crystals oriented in sealed cavities are used, and especially in the optics field for making optic lenses or optic glass.

An example of such an optic element is illustrated in FIG. 1, having a width L of up to 100 mm or more.

It comprises a network of independent micro-cups or micro-cavities 2, separated by walls 6. These micro-cavities are structured on a supple and plane substrate.

It can then be filled with a liquid 4 appropriate to the desired optic effect.

Next, the cavities are closed by a closure layer 9 made of a supple material, generally stuck to the tops of the walls 6.

The whole is formed on a support, in the illustrated example, comprising a substrate 1 made of a material such as quartz and a layer 8 made of a polymer material.

Such an optic element can contain a number of micro-cups numbering between one hundred thousand and ten million.

The walls 6 must be the least visible possible, imposing a strong aspect ratio (or form factor), with minimal wall widths for a resin height in the desired range (5 to 50 μm).

The walls, and the micro-cavities, can be obtained by a process of collective micro-technology type, or by anisotropic etching of a resin selected for its structural properties.

In certain cases, there is a preference to use, as functional fluid in the cavities, liquid crystals; the latter are oriented in the plane of the cavities intended to be sealed. These liquid crystals are aligned by friction of a layer 5 of polyimide placed essentially at the base of the cavity, but also along the walls 6.

This technique is illustrated schematically in FIG. 2. After deposit of the layer 5 on the already structured assembly, the latter is rubbed by a brush, the hairs of which are designated by reference numeral 9.

This technique poses a certain number of problems.

First, the zones of the layer 5, situated on either side of the walls 6, and at the feet thereof, and designated by reference numerals A0, A′0, A1, A′1 in FIG. 2, are not treated satisfactorily as they are not properly rubbed by the brush. This results in an optic effect known as “shading”.

In the plane of the device, these zones have a width of the order of a few μm to around ten μm. They testify to a uniform spreading difficulty of the layer 5 on the topology of the structures.

Also, the passage of the brush causes projections 7, 7′ of polyimide and redeposits of polyimide, or other specific contaminations.

All of this, just as much the shading effect as the specific contamination, contributes to optical defects, visible on the layer 5 of polyimide. Since the latter layer is sensitive, it is not possible to make it before the photolithography process of the cavities. Yet, such optic defects are redhibitory for the optic application in question.

The problem arises of finding a novel process for making cavities with an orientation layer of liquid crystals.

### EXPLANATION OF THE INVENTION

The invention relates initially to a process for formation of cavities of a micro-optic device, comprising:

a) formation, on the plane surface of a support substrate, of a liquid crystal alignment layer,

b) formation of walls of said cavities, the base of said cavities being formed by said alignment layer.

According to the invention, the alignment layer is generated first, for example a layer of polyimide with its friction, before forming or structuring of the walls. The alignment layer can thus be continuous and substantially uniform during its spreading, as the walls are not yet formed. Its friction can thus take place prior to forming of the walls, in optimal conditions.

According to a particular embodiment, step b) comprises depositing then etching of a resin layer to form said walls of the cavities.

A process according to the invention can further comprise:

a′) deposit of a sacrificial protective layer on said alignment layer between steps a) and b),

b′) and, after step b), an elimination step of the sacrificial protective layer between the walls of the cavities.

The invention thus relates in particular to a process for formation of cavities of a micro-optic device, comprising, in this order:

formation, on the plane surface of a support substrate, of a liquid crystal alignment layer,

deposit of a sacrificial protective layer on said alignment layer,

formation of walls of said cavities, by deposit then etching of a resin layer,

elimination of the sacrificial protective layer between the walls of the cavities.

In this particular embodiment of the invention, the alignment layer is protected by a sacrificial layer, structuring (forming of the walls) is completed, and finally the sacrificial layer is removed. The latter allows the properties of the alignment layer to be conserved in the active state. This avoids all sources of contamination and generation of defects such as explained hereinabove in connection with FIG. 2.

The alignment layer is preferably protected by a sacrificial layer of a transparent material.

This sacrificial layer can be a deposited layer, for example by vacuum deposit by a low-temperature process, and it is suitable to be withdrawn by a gentle process vis-à-vis the subjacent alignment layer, such as wet chemistry. This sacrificial layer is advantageously made of silica or an organosilica material, but may also be a resin.

The sacrificial layer cannot be etched before step b), or else the process can comprise, before step b), etching of at least the sacrificial layer to define the position of the walls.

In an embodiment, such a process (with deposit of a sacrificial layer) further includes, after step a′) and before step b):

formation of an etching mask layer on the sacrificial layer and the opening of this mask layer to define the position of the walls,

etching of at least the sacrificial layer through the mask layer,

and, after step b) but before step b′):

elimination of the etching mask layer.

The alignment layer cannot be etched under the sacrificial layer. In this case, the walls are formed above, or on, the alignment layer, which can thus remain continuous and uniform from one cavity to the other, without being affected by any of the forming operations of the walls.

As a variant, the process comprises, before step b), etching of the alignment layer under the etched zones of the sacrificial layer.

A process according to the invention can further comprise, before step b), etching of the substrate under the etched zones of the alignment layer and of the sacrificial layer.

Before deposit of the alignment layer, an ITO layer can be deposited, this layer not being etched before step b).

The invention also relates to a process for formation of a liquid crystal micro-optic device, comprising:

formation of cavities of this device, comprising the use of a process such as hereinabove,

introduction of liquid crystals to said cavities of the device,

formation of a closure layer on the walls of the cavities.

The invention also relates to a liquid crystal micro-optic device, comprising cavities delimited by walls, each cavity being filled at least partially by liquid crystals, an alignment layer for liquid crystals, preferably plane and uniform, being placed at the base of each cavity.

The alignment layer can be continuous from one cavity to the other and can pass under the walls.

A residual portion of sacrificial material can be present under each wall.

According to an embodiment, the walls separate the alignment layers of adjacent cavities.

A layer of ITO material can be placed under the alignment layer. This layer is continuous, and is not etched.

As a variant, the feet of the walls are situated in the substrate.

According to an example, the alignment layer is a layer of rubbed polyimide.

From the geometric viewpoint, the walls can have a height of the order of several μm to several tens of μm, for example greater than 10 μm, and/or a width of the order of several μm or submicronic, for example less than 5 μm or between 5 μm and 0.5 μm.

### BRIEF DESCRIPTION OF THE DRAWINGS

FIG. 1 illustrates a known cavity structure.

FIG. 2 illustrates a known process for preparation of a layer of polyimide.

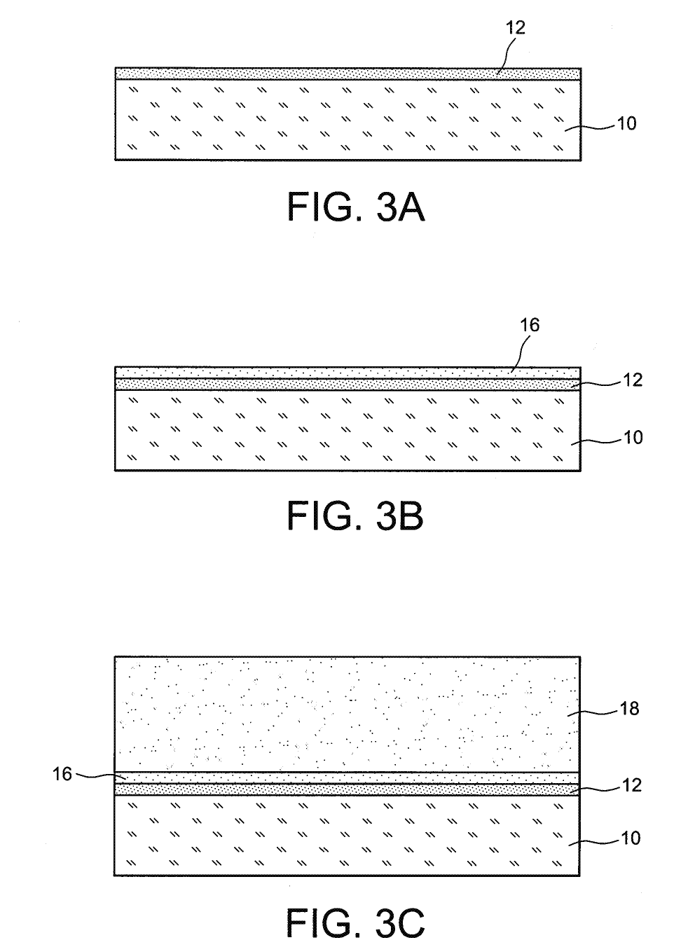

FIGS. 3A-3E illustrate steps for carrying out a process according to the invention.

FIGS. 4A-4G illustrate certain steps for carrying out another process according to the invention.

FIGS. 5A-5B illustrate a variant of a process according to the invention.

FIG. 6 illustrates an operation for filling cavities with a liquid.

### DETAILED EXPLANATION OF PARTICULAR EMBODIMENTS

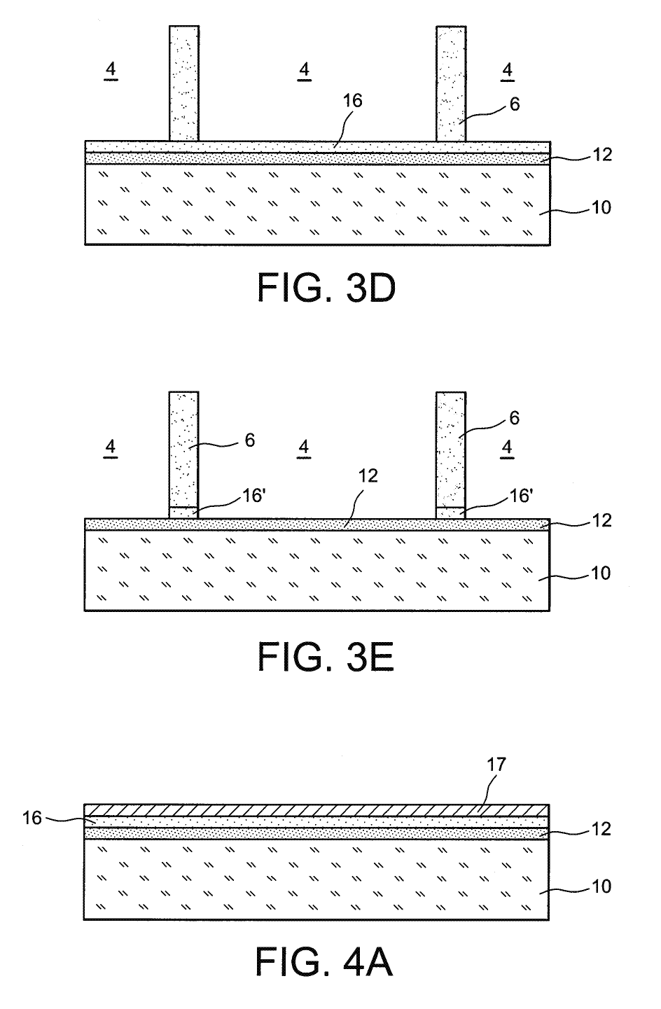

A first embodiment of the invention will now be described in connection with FIGS. 3A-3E.

A support, which can consist of a simple substrate 10, for example made of a polymer material such as PET, is formed first.

A plane liquid crystal alignment layer or a plane film 12 is deposited onto the plane surface of this same substrate 10, for example by a technique of “spincoating” type or by “flexoprinting” (FIG. 3A). A film 12 of polyimide or a film of silica or even a film of PTFE (polytetrafluoroethylene) will be used as an example. This film can have a thickness of up to 20 μm. It is continuous on the substrate 10.

Friction from this film 12 can be caused. This layer or this film can be slightly grooved by friction with an appropriate fabric.

Next (FIG. 3B), in light of the protection of the alignment layer 12 during making of the walls 6, a continuous sacrificial layer 16 is deposited on this layer or film 12. This layer 16 is advantageously transparent to benefit the optical properties of the device. For example, this is a layer of SiO₂, 50 nm in thickness. A feasible deposit technique is the PECVD technique.

The alignment layer 12 is not degraded during the following process, in particular when the sacrificial layer 16 being used is a resin. When this sacrificial layer 16 is made of silica, it is preferably deposited at low temperature to prevent degradation of the friction of the alignment layer 12.

The next step is structuring of the walls 6 of the micro-cavities 4.

A thick resin 18 is then deposited onto the sacrificial layer 16 for this purpose (FIG. 3C). This resin is then etched (FIG. 3D), for example by lithography, with an appropriate mask, or by reactive ionic etching (RIE) using a hard mask which is then eliminated. This is how the walls 6 of the cavities 4 are formed.

The sacrificial layer 16 is at first not affected by this operation, or only slightly so. But it is then eliminated at the base of each micro-cavity, except for the portion of this layer situated under the walls 6, to conserve adherence of the latter (FIG. 3E). A portion 16′ of sacrificial material remains below each wall 6. This step is done by a gentle process, selective relative to the layer 12, affecting the latter as little as possible. This can be for example HF etching, with an adequate surfactant for limiting the over-etching under the walls 6 to a maximum. BE3O:1 gives good results.

The result is a structure comprising the alignment layer 12, rubbed, localised at the base of the cavities 4.

This layer is continuous, flat, and extends under the walls 6, under which subsists a residue 16′ of sacrificial layer.

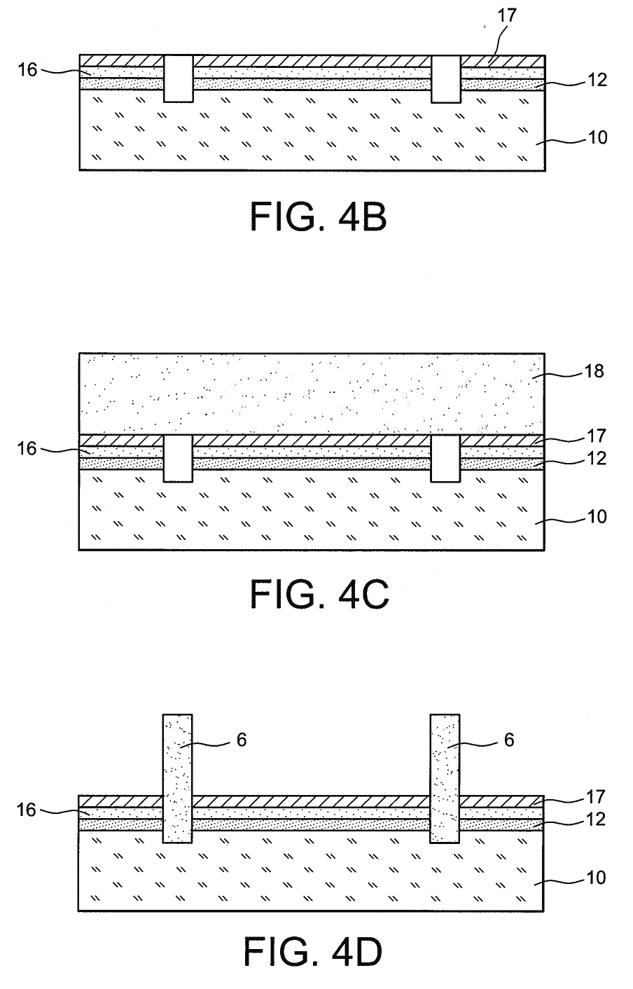

Another embodiment of the invention will now be described in connection with FIGS. 4A-4E.

The two first steps are identical to those described hereinabove, in connection with FIGS. 3A and 3B, and consequently will not be repeated. The same applies for the remarks made hereinabove on the nature of the alignment layer 12 and of the sacrificial layer 16.

A hard mask layer 17 (FIG. 4A), which is structured, is deposited on a substrate identical to that of FIG. 3B. This layer is for example a layer 17 of chromium, 50 nm in thickness. Lithography on this layer 17 is then completed, which can then be etched by reactive ionic etching (RIE) to make an appropriate mask.

This RIE etching step can be continued to also open the sacrificial layer 16 and the alignment layer 12. The layer 16 can possibly be opened or etched without opening or etching the layer 12, thus conserving a continuous alignment layer to produce better adherence of the upper layers.

This etching step defines the form of the future walls 6 of the cavities 4. The walls will in effect be implanted in the etched zones.

Etching in the layers 16 and 12 can be prolonged in the material of the substrate 10, which then reinforces the mechanical performance of the walls 6 (FIG. 4B).

Finally, the resin utilised for lithography is removed.

A resin 18 (FIG. 4C) is then spread, which penetrates into the etched zones, optionally including into the substrate 10.

Next, the walls 6 of the micro-cavity are formed in this resin 18, by lithography, insolation by the rear face 10′ of the substrate 10 and development (FIG. 4D). The rear face 10′ is that opposite the face on which the layers 12, 16, 17 have been deposited.

The mask layer 17 is then eliminated (FIG. 4E), by humid CrEtch etching (brand name of a chrome etching solution) for the case of a Cr layer.

The sacrificial layer 16 is then eliminated (FIG. 4F), here also by a gentle process, selective relative to the layer 12, affecting the latter as little as possible. HF attack and optional surfactant are for example employed (see indications already given hereinabove in connection with FIG. 3E). The alignment layer of each cavity is separated, by the walls 6, from the alignment layer in the adjacent cavities.

In the case of the presence of an ITO sublayer 20 (below the alignment layer 12, thus deposited before the latter on the substrate 10), etching of the openings stops on the ITO layer (FIG. 4G). The layers 17 and 16 can be eliminated from the structure of FIG. 4G, as already indicated hereinabove. The ITO layer is continued, whereas the alignment layer of each cavity is separated, by the walls 6, from the alignment layer in the adjacent cavities.

The result of this also is a structure comprising the alignment layer, for example made of rubbed polyimide, at the base of the cavities 4.

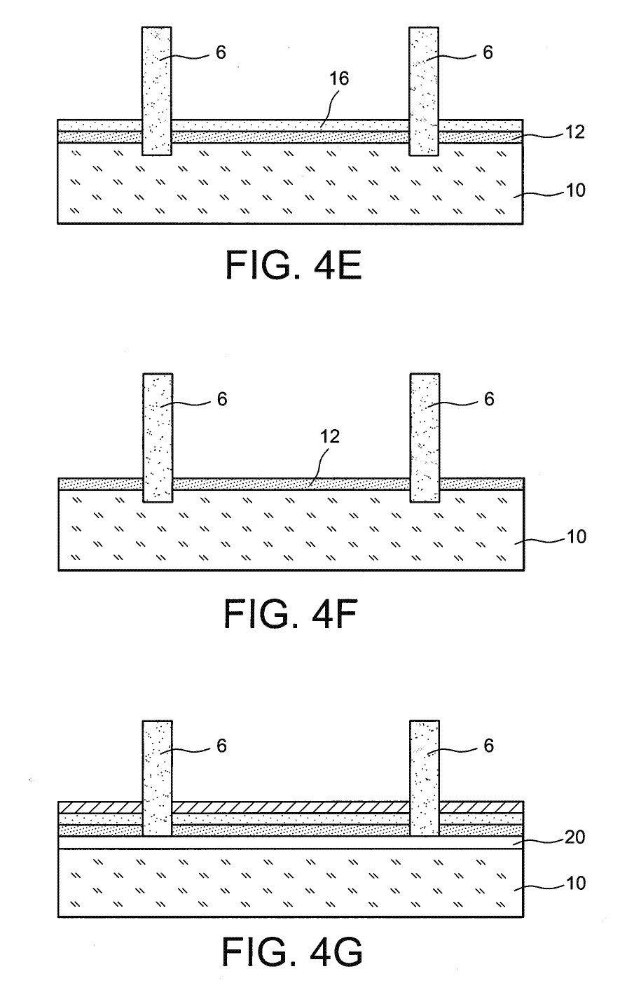

A variant of this embodiment is illustrated in FIGS. 5A and 5B. The preceding steps are identical to those described hereinabove in connection with FIGS. 4A and 4B. But here the etching step of the openings in the layer 17 affects neither the sacrificial layer 16 nor the alignment layer 12.

The final device, after deposit of the resin 18, etching of the walls 6, elimination of the layers 17 and 16, is that of FIG. 5B. A portion 16′ of sacrificial material remains below each wall 6.

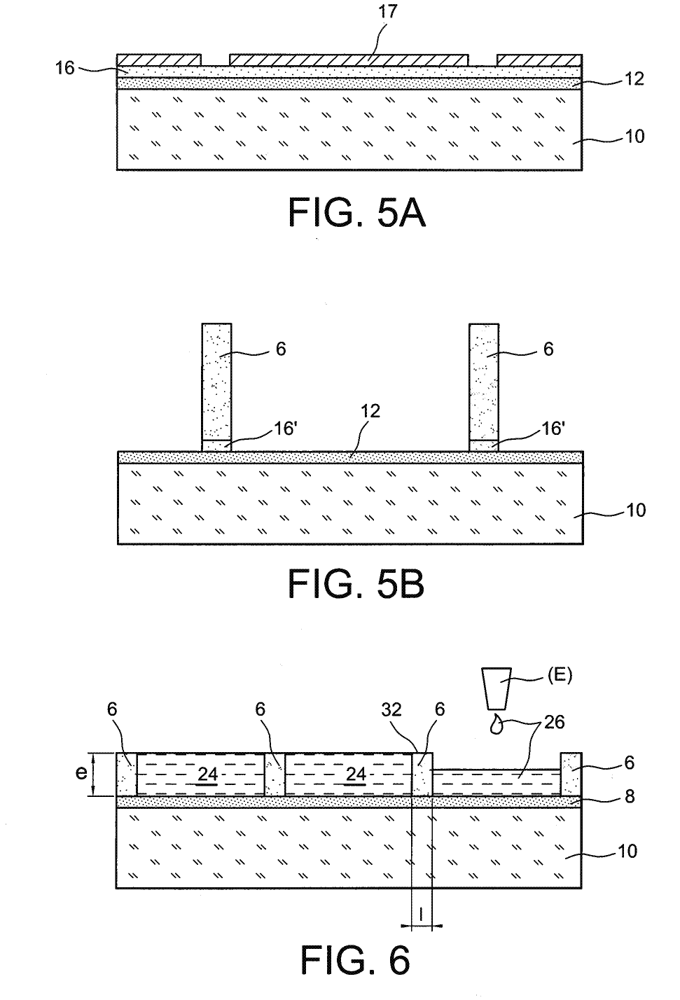

In any case the result is a structure comprising cavities 4 delimited by walls 6, an alignment layer 12 for liquid crystals being placed at the base of each cavity. This layer is plane and uniform at the base of each cavity. It can be continued under all the walls 6 (case of FIGS. 3E and 5B) or separated by the walls 6 from the alignment layer of the adjacent cavities as in FIG. 4F or 4G. In any case, there is no shading effect or specific contamination, but for what has been described hereinabove in connection with the prior art. The walls 6 can have a height e of the order of several μm to several tens of μm and for example greater than 10 μm. Their width 1 (see FIG. 6) can be of the order of several μm or submicronic, for example less than 5 μm or between 5 μm and 0.5 μm.

Filling one or more cavities can then be done by equipment E (FIG. 6) aimed at the interior of the cavities 4 and projecting the liquid material 24 in the form of a jet or drops 26, of a volume which can be of the order of several picolitres. The liquid can be delivered using a technique adapted to low-volume localisation, or several tens to hundreds of picolitres. The equipment E utilised can employ a liquid-dispensing technique similar to that of ink-jet dispensing.

The liquid material 24 can fill the cavities 4 partially or completely. Total filling of the cavities can be done so as to reach the top 32 of the walls 6.

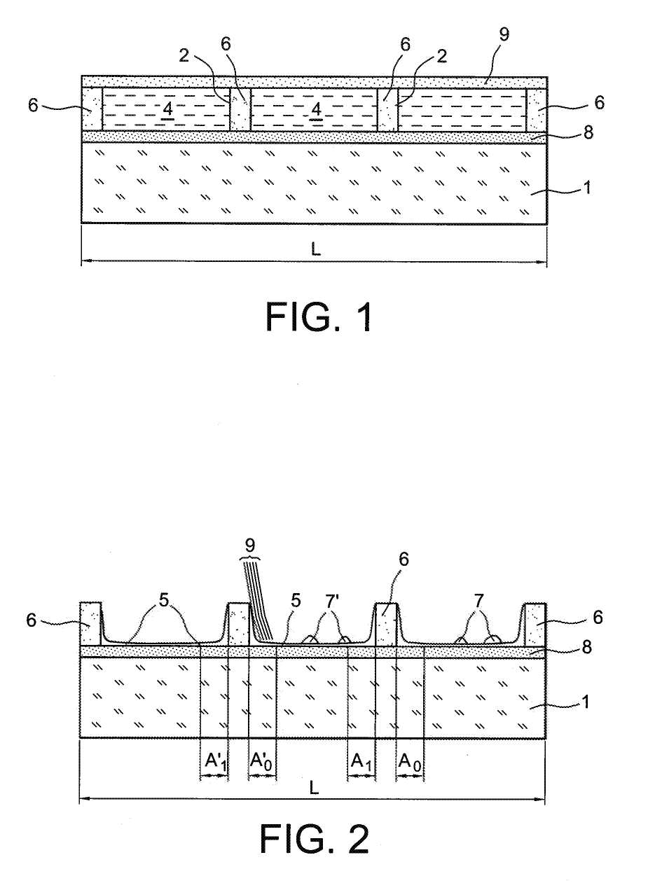

The product is terminated by the transfer (in the simplest case by laminating) of a protective film 9 (FIG. 1), such as a plastic film, identical or not to the material of the support 10. This film is optionally covered by functional layers adapted for the final function (antireflecting, hard layers, anti-fouling, . . . ).

Individualisation of the final product is completed prior to its transfer to the final surface. This individualisation can be done advantageously on the rigid support having served to carry out stacking, though this is not a necessity. If the individualisation takes place on the realisation support, the latter can be done by laser, by ultrasound or by cutting tool. A technique having the following qualities will be preferred: ensuring pre-sealing of the periphery, ensuring good surface state of the slice for optimum sealing, rapid execution adapted to industrialisation. This individualisation is accompanied by peripheral sealing ensuring tightness to gas and humidity, good mechanical performance over the lifetime of the product, a visual quality adapted to consumer products (when necessary, for example for spectacles).

With the invention it is possible to obtain a device without projections 7, 7′ on the alignment layer (to the difference with FIG. 1) and without shading effect, resulting from deposition of material on both sides of walls 6, along said sides perpendicular to the substrate (here again to the difference with FIG. 1). With the invention such lateral deposition on sides of the walls 6 do not happen.

1. A process for formation of cavities of a micro-optic device, comprising:
a) formation, on the surface plane of a support substrate, of an alignment layer of liquid crystals,
b) the deposition of a sacrificial protective layer (16) on said alignment layer,
c) then, formation of walls of said cavities, and elimination of the sacrificial protective layer between the walls of the cavities, the base of said cavities being formed by said alignment layer.

2. The process as claimed in claim 1, step c) comprising deposition of a resin layer and then etching of said resin layer so as to form said walls of the cavities.

3. The process as claimed in claim 1, the sacrificial layer not being etched before step c).

4. The process as claimed in claim 1, further comprising, before step c), etching of parts of at least the sacrificial layer to define the position of the walls.

5. The process as claimed in claim 1, further comprising, after step b) and before step c):
formation of an etching mask layer on the sacrificial layer and opening of this mask layer to define the position of the walls,
etching of parts of at least the sacrificial layer through the mask layer,
and, after formation of the walls of said cavities, but before elimination of the sacrificial protective layer:
elimination of the etching mask layer.

6. The process as claimed in claim 4, the alignment layer not being etched under the sacrificial layer.

7. The process as claimed in claim 4, further comprising, before step c), etching of zones or parts of the alignment layer under the etched zones of the sacrificial layer.

8. The process as claimed in claim 7, further comprising, before step c), etching of parts of the substrate under the etched zones or parts of the alignment layer and of the sacrificial layer.

9. The process as claimed in claim 1, comprising, before deposit of said alignment layer, the deposit of an ITO layer, this layer not being etched before step c).

10. The process as claimed in claim 1, said alignment layer being a layer of rubbed polyimide.

11. A process for formation of a liquid crystal micro-optic device, comprising:
formation of cavities of this device, comprising the use of a process as claimed in claim 1,
introduction of liquid crystals to said cavities of the device,
formation of a closing layer on the walls of the cavities.

12. A process for formation of cavities of a micro-optic device, comprising:
a) formation, on the surface plane of a support substrate, of an alignment layer of liquid crystals,
b) the deposition of a sacrificial protective layer on said alignment layer,
c) etching of parts of at least the sacrificial layer to define the position of the walls,
c) then, formation of walls of said cavities, and an elimination of the sacrificial protective layer between the walls of the cavities, the base of said cavities being formed by said alignment layer.

13. A micro-optic liquid crystal device comprising cavities delimited by walls, a portion of sacrificial material laying below each wall, each cavity being filled at least partially by liquid crystals, an alignment layer for liquid crystals being placed at the base of each cavity.

14. The device as claimed in claim 13, the alignment layer being plane and uniform.

15. The device as claimed in claim 13, the alignment layer being continued from one cavity to the other and passing under the walls.

16. The device as claimed in claim 13, further comprising a layer of ITO material, placed under the alignment layer.

17. The device as claimed in claim 13, said alignment layer being a layer of rubbed polyimide.

18. The device as claimed in claim 13, the walls having a height of the order of a few μm to several tens of μm.

19. The device as claimed in claim 13, the walls having a width of the order of a few μm or submicronic.
